(19) United States
(12) Patent Application Publication
(10) Pub. No.: US 2016/0322110 A1
(43) Pub. Date: Nov. 3, 2016

(54) SEMICONDUCTOR STORAGE DEVICE AND CONTROL METHOD OF SEMICONDUCTOR STORAGE DEVICE

(71) Applicant: Kabushiki Kaisha Toshiba, Minato-ku (JP)

(72) Inventors: Naofumi ABIKO, Kawasaki (JP); Yoshikazu HARADA, Kawasaki (JP)

(73) Assignee: Kabushiki Kaisha Toshiba, Minato-ku (JP)

(21) Appl. No.: 14/833,377

(22) Filed: Aug. 24, 2015

Related U.S. Application Data
(60) Provisional application No. 62/153,692, filed on Apr. 28, 2015.

(51) Int. Cl. G11C 16/24; G11C 16/26; G11C 16/34

(52) U.S. Cl. CPC G11C 16/24; G11C 16/3459; G11C 16/26

(57) ABSTRACT

According to one embodiment, there is provided a semiconductor storage device including a memory cell array and a control circuit. The memory cell array has multiple memory cells connected to word lines and bit lines. The control circuit sets a value of a control voltage used to control voltages on the bit lines at a first value and, if receiving a first command including a change request to change the control voltage and including a to-be-changed-to second value, changes the value of the control voltage used to control the voltages on the bit lines from the first value to the second value, according to the change request.

### CROSS-REFERENCE TO RELATED APPLICATIONS

This application is based upon and claims the benefit of priority from U.S. Provisional Application No. 62/153,692, filed on Apr. 28, 2015; the entire contents of which are incorporated herein by reference.

### FIELD

Embodiments described herein relate generally to a semiconductor storage device and a control method of the semiconductor storage device.

### BACKGROUND

In semiconductor storage devices such as NAND flash memories, writing processing/erasing processing of data into/from a memory cell applies a high voltage across the substrate and the control gate, thereby injecting/ejecting electrons into/from the floating gate. As writing processing/erasing processing of data into/from a memory cell is performed multiple times, the gate insulating film around the floating gate tends to degrade, so that the ON current of the memory cell can decrease.

### BRIEF DESCRIPTION OF THE DRAWINGS

FIG. 1 is a diagram showing the configuration of a semiconductor storage device according to an embodiment;

FIG. 2 is a diagram showing the configuration of a memory package in the embodiment;

FIG. 3 is a diagram showing the configuration of a memory chip in the embodiment;

FIG. 4 is a diagram showing the configuration of a memory cell array, row control circuit, and read circuit in the embodiment;

FIG. 5 is a diagram showing the configuration of a sense amplifier in the embodiment;

FIG. 6 is a diagram showing the operation of the sense amplifier in the embodiment;

FIG. 7 is a diagram showing the operation of the sense amplifier in the embodiment;

FIG. 8 is a diagram showing an example command sequence of a command (set feature command) including a request to change a control voltage in the embodiment;

FIG. 9 is a flow chart showing the operation of a host and the semiconductor storage device in the embodiment;

FIG. 10 is a sequence diagram showing the operation of the host, memory controller, and memory chip in the embodiment;

FIG. 11 is a sequence diagram showing the operation of the host, memory controller, and memory chip in the embodiment;

FIG. 12 is a diagram showing an example command sequence of a command (prefix command) including a request to change the control voltage in a modified example of the embodiment;

FIG. 13 is a sequence diagram showing the operation of the host, memory controller, and memory chip in the modified example of the embodiment; and

FIG. 14 is a sequence diagram showing the operation of the host, memory controller, and memory chip in the modified example of the embodiment.

### DETAILED DESCRIPTION

In general, according to one embodiment, there is provided a semiconductor storage device including a memory cell array and a control circuit. The memory cell array has multiple memory cells connected to word lines and bit lines. The control circuit sets a value of a control voltage used to control voltages on the bit lines at a first value and, if receiving a first command including a change request to change the control voltage and including a to-be-changed-to second value, changes the value of the control voltage used to control the voltages on the bit lines from the first value to the second value, according to the change request.

Exemplary embodiments of a semiconductor storage device will be explained below in detail with reference to the accompanying drawings. The present invention is not limited to the following embodiments.

### Embodiment

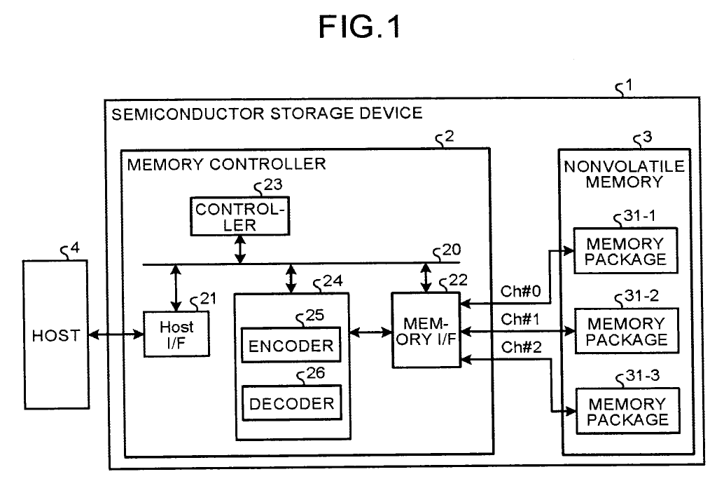

A semiconductor storage device according to the embodiment will be described using FIG. 1. FIG. 1 is a diagram showing the configuration of the semiconductor storage device 1. The semiconductor storage device 1 is connected to a host 4 and functions as an external storage medium for the host 4. The semiconductor storage device 1 is, for example, a flash memory for embedded use compliant with the UFS (Universal Flash Storage) standard, the eMMC (embedded Multi Media Card) standard, or the like, or an SSD (Solid State Drive). The host 4 is, for example, a personal computer, a mobile telephone, an imaging device, or the like.

The semiconductor storage device 1 has a nonvolatile memory 3 and a memory controller 2.

The nonvolatile memory 3 is, for example, a NAND flash memory and can store data in a nonvolatile manner. The nonvolatile memory 3 has a plurality of, here three, memory packages 31-1 to 31-3 that are access controlled in parallel with each other, and the memory packages 31-1 to 31-3 are connected to the memory controller 2 via signal line groups (channels Ch#0 to Ch#2) respectively independently of each other. Although herein the number of memory packages that the nonvolatile memory 3 has is three, the number of memory packages provided in the nonvolatile memory 3 needs only be greater than or equal to one, not being limited to three.

The memory controller 2 controls writing data into the nonvolatile memory 3 according to a program command (write request and data) from the host 4. The memory controller 2 controls reading data from the nonvolatile memory 3 according to a read command (read request) from the host 4. The memory controller 2 has a host interface (host I/F) 21, a memory interface (memory I/F) 22, a controller 23, and an error correcting unit 24. The error correcting unit 24 has an encoder 25 and a decoder 26. The host I/F 21, memory I/F 22, controller 23, encoder 25, and decoder 26 are connected to each other via an internal bus 20.

The host I/F 21 performs processing according to the interface standard between itself and the host 4 and outputs a request received from the host 4, user data, and the like onto the internal bus 20. The interface standard includes, for example, the ATA (Advanced Technology Attachment) standard. The host I/F 21 transmits user data read from the nonvolatile memory 3, a response from the controller 23, and the like to the host 4.

The memory I/F 22 issues and supplies a program instruction to the nonvolatile memory 3 based on a program command (write request) from the host 4 so as to control the write processing of writing data into the nonvolatile memory 3.

The memory I/F 22 issues and supplies a read instruction to the nonvolatile memory 3 based on a read command (read request) from the host 4 so as to control the read processing of reading data from the nonvolatile memory 3. For example, the memory I/F 22 issues and supplies a normal read instruction to the nonvolatile memory 3 based on a normal read command (first read request) from the host 4 so as to control the read processing (first read operation) of reading data from the nonvolatile memory 3. The memory I/F 22 issues and supplies a retry read instruction to the nonvolatile memory 3 based on a retry read command from the host 4 so as to control the retry read processing (second read operation) of reading data from the nonvolatile memory 3 under conditions for reading of higher reliability.

The retry read processing may be shift read processing that performs reading while shifting the read voltage from a default value, or DLA (Direct Look Ahead) processing that performs reading while changing the read voltage so as to correct for a proximity effect. The proximity effect is that the threshold voltage of a selected memory cell is affected by data in adjacent memory cells to vary. Further, the retry read processing may be controlled by the memory I/F 22 in response to the controller 23 determining that the retry read processing should be performed, instead of being performed according to a retry read command from the host 4.

The memory I/F 22 is connected to each of the memory packages 31-1 to 31-3 via signal lines independently and performs read processing/write processing independently for each channel.

The controller 23 is one which controls the components of the memory controller 2 overall. When receiving a command from the host 4 via the host I/F 21, the controller 23 performs control according to that command.

The encoder 25 performs error correction encoding based on user data transferred over the internal bus 20. Any code may be used as an error correction code, and, for example, the BCH code, the RS (Reed-Solomon) code, or the like can be used.

The decoder 26 determines whether there is an error in user data based on code words (the user data and parity) read from the nonvolatile memory 3 and notifies the determining result to the controller 23. Further, if there is an error in the user data, the decoder 26 performs error correction using the parity according to an instruction from the controller 23 and then outputs the user data and the number of uncorrectable bits (the number of bad bits) onto the internal bus 20. Thus, the controller 23 can transmit the user data and information about the number of bad bits as the reading result to the host 4 via the host I/F 21.

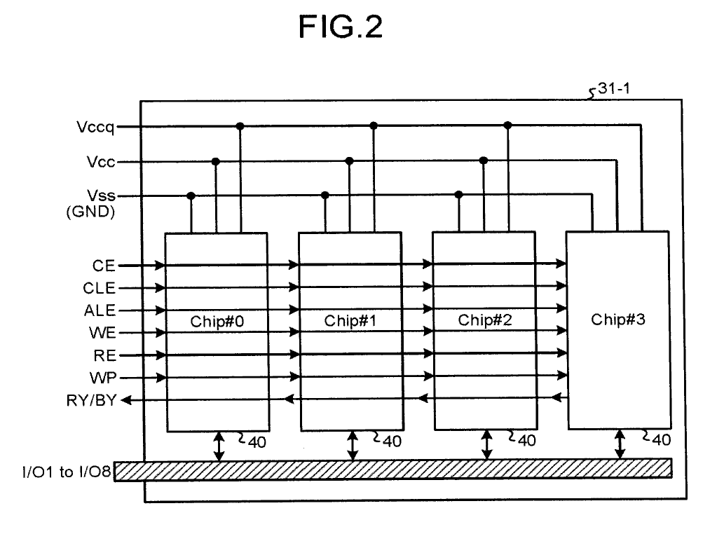

Next, the configuration of each memory package 31 will be described using FIG. 2. FIG. 2 is a diagram showing the configuration of the memory package 31-1. The memory packages 31-2, 31-3 have similar configuration to that of the memory package 31-1.

The memory package 31-1 has four memory chips 40 (Chip#0 to Chip#3). Note that the number of memory chips provided in the memory package 31-1 may be greater than or equal to one, not being limited to four. Data is written into and read from each memory chip 40 in data units called pages. As shown in the figure, control signal lines for controlling the memory chips 40, an I/O (Input/Output) signal line via which commands, addresses, and data are transmitted, and potential supply lines are connected to the memory package 31-1.

Note that the control signal lines include a chip enable signal (CE), a command latch enable signal (CLE), an address latch enable signal (ALE), a write enable signal (WE), a read enable signal (RE), and a write protection signal (WP), a ready/busy signal (RY/BY). The potential supply lines supply a power supply potential Vcc, a for-the-interface-circuit power supply potential Vccq, and a ground potential Vss. As shown in the figure, the control signal lines and the I/O signal line are lines common to the memory chips in the memory package 31-1. Herein, the I/O signal line is a signal line with eight-bit width as an example, but the transmission width of the I/O signal line is not limited to eight bits.

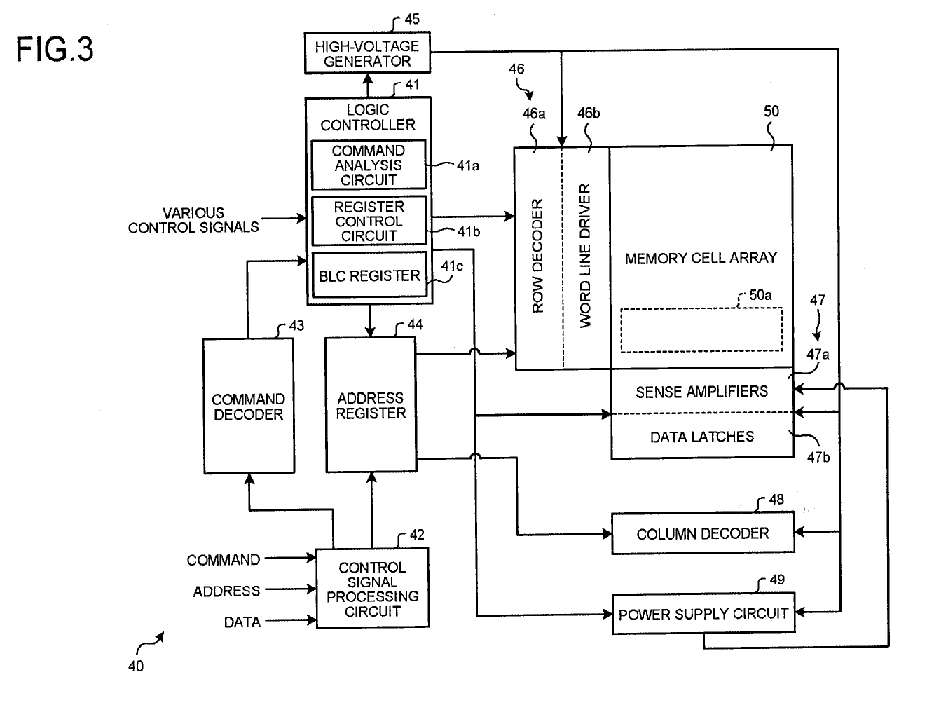

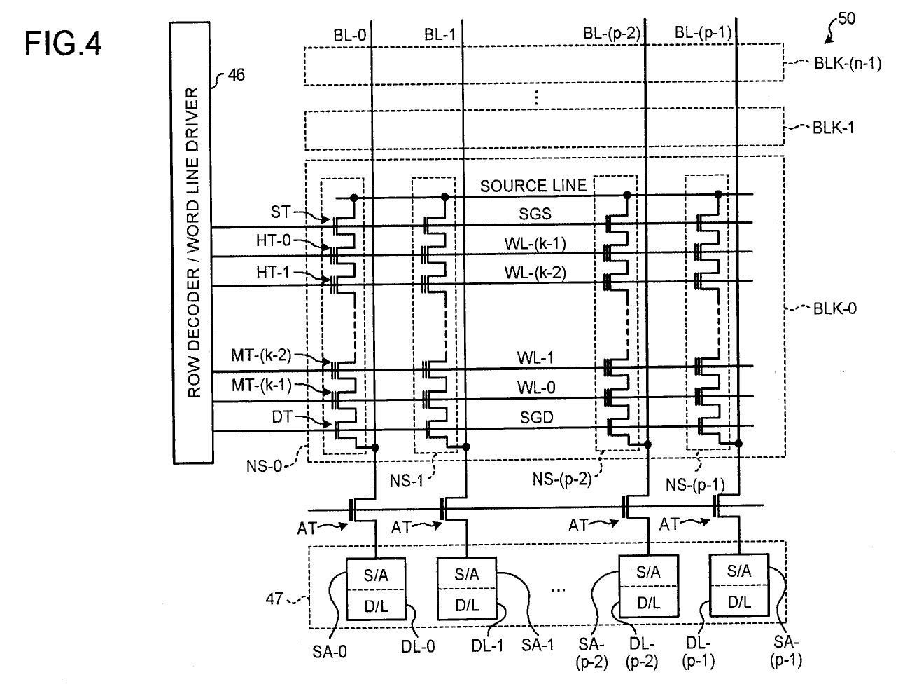

Next, the configuration of each memory chip 40 will be described using FIGS. 3 and 4. FIG. 3 is a block diagram showing the configuration of the memory chip 40. FIG. 4 is a circuit diagram showing the configuration of a memory cell array 50.

The memory chip 40 has a logic controller (control circuit) 41, a control signal processing circuit 42, a command decoder 43, an address register 44, a high-voltage generator 45, a row control circuit 46, a read circuit 47, a column decoder 48, a power supply circuit 49, and the memory cell array 50.

The memory cell array 50 comprises multiple memory cells. The multiple memory cells form multiple rows and multiple columns. As shown in, e.g., FIG. 4, the memory cell array 50 includes n number of blocks BLK-0 to BLK-(n−1), where n is a positive integer. In each block BLK-0 to BLK-(n−1), multiple NAND strings NS-0 to NS-(p−1) are arranged. The NAND strings NS-0 to NS-(p−1) each extend in a column direction, for example. The NAND strings NS-0 to NS-(p−1) are arranged along a row direction. Each NAND string NS-0 to NS-(p−1) includes, e.g., multiple memory cells MT-0 to MT-(k−1) connected in series and two select gates ST, DT connected to opposite ends thereof one each (see FIG. 4).

Multiple word lines each extend in a row direction. The multiple word lines are arranged along a column direction. As shown in, e.g., FIG. 4, the word lines WL-0 to WL-(k−1) each extend in a row direction. The word lines WL-0 to WL-(k−1) are arranged along a column direction. That is, the word lines WL-0 to WL-(k−1) cross the NAND strings NS-0 to NS-(p−1). The word lines WL-0 to WL-(k−1) are connected to the control gates of the memory cells.

Each memory cell MT is, for example, an MLC (Multi-Level Cell) and can store a multiple value using an upper page and a lower page. Or each memory cell MT may be a TLC (Triple Level Cell) storage cell. Where each memory cell MT is a TLC (Triple Level Cell) storage cell, one memory cell can store three-bit information. In the case of the TLC, three pages that are an upper page, a middle page, and a lower page are connected to one word line WL.

Two select gate lines SGD, SGS each extend in a row direction. The select gate lines SGD, SGS are placed at opposite ends of the arrangement along a column direction of the word lines. The two select gate lines SGD, SGS are connected to the control gates of the select gates DT, ST respectively.

Multiple bit lines each extend in a column direction. The multiple bit lines are arranged along a row direction. As shown in, e.g., FIG. 4, the bit lines BL-0 to BL-(p−1) each extend in a column direction. The bit lines BL-0 to BL-(p−1) are arranged along a row direction. That is, the bit lines BL-0 to BL-(p−1) correspond to the NAND strings NS-0 to NS-(p−1).

Each NAND string NS is connected to a common source line via the corresponding select gate ST. Further, each NAND string NS is connected to the corresponding bit line BL via the corresponding select gate DT.

The logic controller 41 shown in FIG. 3 is a state transition circuit (state machine) whose state transitions based on various control signals (control signals CE, CLE, ALE, WE, RE, WP shown in FIG. 2) received from the memory controller 2 and controls the operation of the entire memory chip 40.

The control signal processing circuit 42 is a buffer circuit for transmitting and receiving an I/O signal to and from the memory controller 2 via the I/O signal line (see FIG. 2). The I/O signal includes a command (chip command), an address, and data. The control signal processing circuit 42 stores a received command into the command decoder 43 and a received address into the address register 44.

The high-voltage generator 45 raises a power supply voltage under the control of the logic controller 41 to supply various voltages corresponding to the raised voltage to the row control circuit 46, read circuit 47, column decoder 48, and power supply circuit 49 respectively. Further, the high-voltage generator 45 supplies a predetermined voltage to the well regions of the memory cell array 50.

The row control circuit 46 has a row decoder 46a and a word line driver 46b. The row decoder 46a is connected to the word lines WL-0 to WL-(k−1) via the word line driver 46b. The word lines WL-0 to WL-(k−1) are respectively connected to the control gates of the memory cells MT of each NAND string NS. The row decoder 46a decodes a row address transferred from the address register 44 to decide on a selected word line and non-selected word lines from among the word lines WL-0 to WL-(k−1). Then at programming operation, the row decoder 46a sets the potential on the selected word line at a programming potential Vpgm (e.g., about 18 V) via the word line driver 46b and the potential on the non-selected word lines at a transfer potential Vpass (e.g., about 10 V). At read operation, the row decoder 46a sets the potential on the selected word line at a read potential Vread and the potential on the non-selected word lines at a non-selected potential.

The read circuit 47 has a sense amplifier block 47a and a data latch block 47b. The sense amplifier block 47a has multiple pairs of a sense amplifier SA-0 to SA-(p−1) and a data latch DL-0 to DL-(p−1) that correspond to the multiple bit lines BL-0 to BL-(p−1). Each pair of a sense amplifier SA and a data latch DL is connected to the corresponding NAND string NS and bit line BL via a high-withstand-voltage transistor AT. At read operation and at program verify operation, the high-withstand-voltage transistor AT is kept in an ON state. Read data detected by the sense amplifier SA is held as, e.g., binary data in the data latch DL paired with the sense amplifier SA.

The column decoder 48 decodes a column address from the address register 44. Further, the column decoder 48 determines whether data held in the data latches DL is to be transferred onto a data bus based on this decoding result. Data transferred onto the data bus is outputted to the memory controller 2 via the I/O signal line.

The power supply circuit 49 generates a predetermined control voltage using a voltage supplied from the high-voltage generator 45 under the control of the logic controller 41 to supply the generated control voltage to the sense amplifier block 47a.

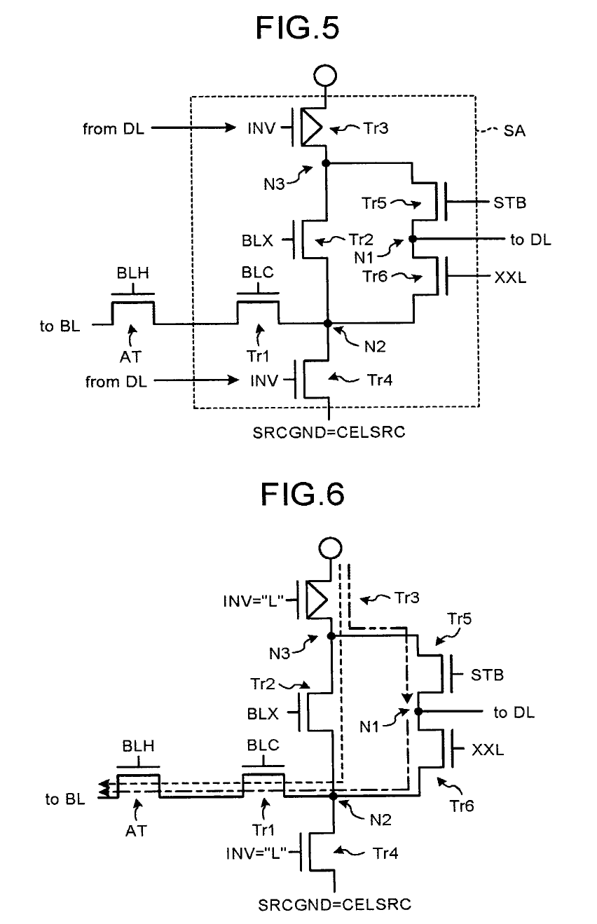

Next, the configuration of the sense amplifier SA will be described using FIG. 5. FIG. 5 is a diagram showing the configuration of the sense amplifier SA (see FIG. 4) connected to a bit line BL. Herein, an example of an ABL (All Bit Line) scheme in which all bit lines are sensed simultaneously will be described.

The sense amplifier SA has multiple transistors Tr1 to Tr6. Of the multiple transistors Tr1 to Tr6, the transistor Tr3 is a PMOS transistor, and the other transistors Tr1, Tr2, and Tr4 to Tr6 are NMOS transistors.

One of the source and drain of the transistor Tr1 is connected to the bit line BL via the high-withstand-voltage transistor AT, and the other is connected to a node N2 with a control voltage BLC being applied to the gate. The power supply circuit 49 (see FIG. 3) generates the control voltage BLC under the control of the logic controller 41 to apply to the gate of the transistor Tr1. For example, the power supply circuit 49 generates the control voltage BLC having a value V1 (first value) to apply to the gate of the transistor Tr1.

The source of the transistor Tr2 is connected to the node N2, and the drain is connected to a node N3 with a control voltage BLX being applied to the gate. The source of the transistor Tr5 is connected to a node N1, and the drain is connected to the node N3 with a control voltage STB being applied to the gate. The source of the transistor Tr6 is connected to the node N2, and the drain is connected to the node N1 with a control voltage XXL being applied to the gate. The power supply circuit 49 (see FIG. 3) generates the control voltages BLX, STB, and XXL under the control of the logic controller 41 to apply to the gates of the transistors Tr2, Tr5, and Tr6 respectively.

The source of the transistor Tr3 is connected to a power supply potential, and the drain is connected to the node N3 with a control voltage INV being supplied from the data latch DL. The source of the transistor Tr4 is connected to a ground potential (SRCGND), and the drain is connected to the node N2 with the control voltage INV being supplied from the data latch DL. The data latch DL (see FIG. 4) latches data of a level that is the logical inverse of the level on the node N1 and applies the level of the latched data, as the level of the control voltage INV, to each of the gates of the transistors Tr3, Tr4.

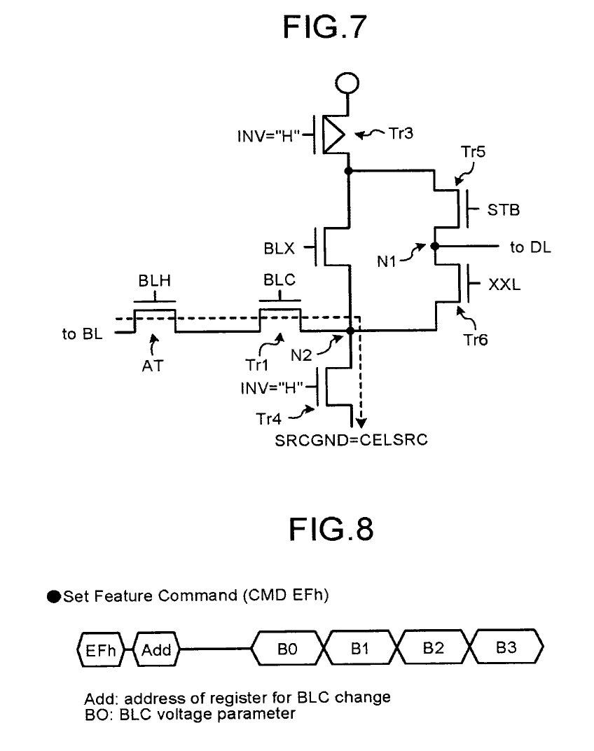

At read operation, for example, if the selected cell in a NAND string NS connected to the bit line BL to which the sense amplifier SA is connected holds data having a value of 1, the sense amplifier SA operates as shown in FIGS. 6 and 7. FIGS. 6 and 7 are diagrams showing the operation of the sense amplifier SA. Note that the high-withstand-voltage transistor AT is kept in an ON state.

For example, during a precharge period, it operates as shown in FIG. 6. Let Vt be the threshold of each transistor. If BLC>Vt, BLX>Vt, STB>Vt, and XXL<Vt, then the transistors Tr1, Tr2, Tr5 turn on, and the transistor Tr6 turns off. Thus, as indicated by a two-dot chain line in FIG. 6, a current flows through the path from the power supply potential→Tr3→N3→Tr5→N1 so as to precharge the node N1 with electric charge. As a result, the potential on the node N1 becomes a high (H) level, so that INV=“L”, and hence the transistor Tr3 turns on with the transistor Tr4 turning off.

At this time, the selected cell holds data having a value of 1, that is, it is in an ON state, so that the wiring capacitance of the bit line BL can be precharged with a current flowing into the source line (see FIG. 4). That is, as indicated by a broken line in FIG. 6, a current (ON current of the memory cell) flows through the path from the power supply potential→Tr3→N3→Tr2→N2→Tr1→AT→BL so as to precharge the wiring capacitance of the bit line BL with electric charge. At this time, letting the control voltage BLC be at V1 (the first value), the potential Vb1 on the precharged bit line BL approximately equals V1−Vt. That is, the potential Vb1 on the precharged bit line BL can be controlled by the value of the control voltage BLC.

Then when STB is made lower than Vt and XXL is made higher than Vt, the transistor Tr5 turns off, and the transistor Tr6 turns on, and hence, as indicated by a dot-dashed line in FIG. 6, a current flows through the path from N1→Tr6→N2→Tr1→AT→BL so as to discharge charge from the charged node N1 into the bit line BL side. Thus, the potential on the node N1 lowers to a low (L) level. When the voltage on the node N1 goes into the state where it can be determined whether the voltage is at 0 or 1, XXL is made lower than Vt, and the H level obtained by inverting the L level on the node N1 is held (latched) in the data latch DL. Because the level of data latched in the data latch DL is the H level, the value of data held in the selected cell can be detected (sensed) as being 1. When this sensing finishes so that data is set in the data latch DL, INV becomes the H level, and hence the transistor Tr3 turns off with the transistor Tr4 turning on. Thus, as indicated by a broken line in FIG. 7, a current flows through the path from BL→AT→Tr1→N2→Tr4→the ground potential (SRCGND) so as to discharge charge from the charged wiring capacitance of the bit line BL into the ground potential, so that the potential Vb1 on the bit line BL approximately equals 0 V.

In contrast, if the selected cell in the NAND string NS connected to the bit line BL to which the sense amplifier SA is connected holds data having a value of 0, the node N1 and the wiring capacitance of the bit line BL are both precharged with charge as in FIG. 6. Then when STB is made lower than Vt and XXL is made higher than Vt, the transistor Tr5 turns off, and the transistor Tr6 turns on. At this time, the selected cell holds data having a value of 0, that is, it is in an OFF state, and hence a current into the source line (see FIG. 4) does not flow, so that discharging charge from the charged node N1 is not performed, but the potential Vb1 on the bit line BL is kept approximately equal to V1−Vt. Thus, the potential on the node N1 does not lower but is kept at the H level. When the voltage on the node N1 goes into the state where it can be determined whether the voltage is at 0 or 1, XXL is made lower than Vt, and the L level obtained by inverting the H level on the node N1 is held (latched) in the data latch DL. Because the level of data latched in the data latch DL is the L level, the value of data held in the selected cell can be detected (sensed) as being 0. When this sensing finishes so that data is set in the data latch DL, INV becomes the L level.

Note that the operation of the sense amplifier SA described using FIGS. 6 and 7 applies to program verify operation that is performed after program operation is performed according to a program command. That is, in the program operation, data is written into the selected memory cell, and in the program verify operation, data held in the selected memory cell is read and detected (sensed) in the same way as above so as to verify whether the data is correctly written therein.

As such, in the read operation or the program verify operation for the value of data held in the memory cell, the amount of ON current of the memory cell affects the difference between the ON state and OFF state (ON/OFF ratio) of the memory cell depending on the potential on the node N1. For example, in the semiconductor storage device 1, in write processing/erase processing of data into/from the memory cell, electrons are injected/ejected into/from the floating gate by applying a high voltage across the substrate and the control gate. As writing processing/erasing processing of data into/from the memory cell is performed multiple times, the gate insulating film around the floating gate tends to degrade, so that the ON current of the memory cell decreases. If the ON current of the memory cell decreases, sensing accuracy in the read operation or the program verify operation decreases, so that the reliability of the read operation or the program verify operation may degrade.

It is desired to increase the ON current of the memory cell correspondingly to degradation of the memory cell in order to suppress degradation in the reliability of the read operation or the program verify operation. As the method of increasing the ON current of the memory cell, one can think of raising the potential Vb1 on the precharged bit line BL to increase the source-to-drain voltage of the memory cell when the memory cell has been degrading. Raising the potential Vb1 on the precharged bit line BL can be achieved by raising the value of the control voltage BLC applied to the gate of the transistor Tr1 to a higher value as above.

However, to what degree to raise the potential Vb1 on the precharged bit line BL can vary depending on compatibility between the semiconductor storage device 1 and the host 4. Accordingly, it is desired that the user of the semiconductor storage device 1, that is, the host 4 side can specify to what degree to raise the potential Vb1 on the precharged bit line BL.

Accordingly, in the present embodiment, the semiconductor storage device 1 is configured in such a way that, when receiving a command (e.g., a set feature command) including a request to change the control voltage BLC and a to-be-changed-to value V2 from the host 4, it changes the value of the control voltage BLC used for controlling the voltage on the bit line BL from V1 to V2 (>V1) according to the request to change. Thus, the user side (the host 4 side) can specify to what degree to raise the potential Vb1 (=BLC value−Vt) on the precharged bit line BL.

Specifically, in the memory chip 40 shown in FIG. 3, the logic controller 41 has a command analysis circuit 41a, a register control circuit 41b, and a BLC register (bit line control register) 41c.

At the startup of the memory chip 40 and the like, the register control circuit 41b reads the initial value V1 (the first value) of the control voltage BLC from a management information storing area 50a in the memory cell array 50 to store the initial value V1 (the first value) of the control voltage BLC into the BLC register 41c.

The logic controller 41 refers to the value V1 stored in the BLC register 41c and controls the power supply circuit 49 to generate the control voltage BLC having the value V1. Thus, the power supply circuit 49 generates the control voltage BLC having the value V1 to apply to the gate of the transistor Tr1 in each sense amplifier SA.

When receiving a command including a request to change the control voltage BLC and the to-be-changed-to value V2 (a second value) from the host 4, the memory controller 2 (see FIG. 1) issues and supplies an instruction (chip command) including that request to change and the to-be-changed-to value V2 to the memory chip 40. The value V2 is higher than the value V1 and specified by the host 4 side.

The command including the request to change the control voltage BLC and the to-be-changed-to value V2 is, for example, a set feature command shown in FIG. 8. The set feature command is a command compliant with the ATA standard and used when the host 4 side sets a predetermined function of the semiconductor storage device 1. In the instruction (for-chip set feature command) issued according to the set feature command, “EFh” that indicates being a set feature is placed at the beginning. Following it, the address “Add” of an access destination is placed, and then data “B0”, “B1”, “B2”, and “B3” are placed.

In the present embodiment, a new specification compliant with the ATA standard is added to the set feature command. That is, as the address “Add”, the address of the BLC register 41c is specified which is decided on so as not to coincide with any of the addresses already defined in the ATA standard. Further, as the data “B0”, the to-be-changed-to value V2 (the second value) is specified.

The command analysis circuit 41a shown in FIG. 3 analyzes the instruction (chip command) from the memory controller 2 to identify the request to change and the to-be-changed-to value V2. For example, the command analysis circuit 41a can interpret the instruction as a set feature instruction because of the “EFh” of the set feature instruction and interprets the address “Add” as a request to change the control voltage BLC if the address of the BLC register 41c is specified by the address “Add”. Then the command analysis circuit 41a, according to the request to change, interprets the value of, e.g., the first data “B0” of the data “B0”, “B1”, “B2”, and “B3” as specifying the to-be-changed-to value V2 (the second value). Then the command analysis circuit 41a, according to the request to change, instructs the register control circuit 41b to change the value V1 of the control voltage BLC to the value V2.

The register control circuit 41b stores the value V2 into the BLC register 41c instead of the value V1 according to the instruction from the command analysis circuit 41a. That is, the register control circuit 41b overwrites/updates the value V1 stored in the BLC register 41c with the value V2.

The logic controller 41 refers to the value V2 stored in the BLC register 41c and controls the power supply circuit 49 to generate the control voltage BLC having the value V2. Thus, the power supply circuit 49 can generate the control voltage BLC having the value V2 to apply to the gate of the transistor Tr1 in each sense amplifier SA. Therefore the potential Vb1 on the precharged bit line BL can be raised according to the specification from the user side (host 4 side).

Note that the command analysis circuit 41a can also analyze other instructions (chip commands). For example, the memory controller 2 issues a read instruction (00h-Add-30h) according to a normal read command from the host 4 to supply to the memory chip 40. The command analysis circuit 41a can interpret the instruction as a read instruction because of the 00h and 30h of the read instruction (00h-Add-30h) from the memory controller 2 and interpret “Add” as the address of an object to read. Thus the logic controller 41 performs read processing. In the read processing, the logic controller 41 performs read operation to read data of interest from the memory cell array 50 into a page buffer (not shown). The logic controller 41 sets the RY/BY signal (see FIG. 2) to indicate a busy state while it is reading data of interest from the memory cell array 50 into the page buffer. Then the logic controller 41 switches the RY/BY signal from the busy state to a ready state after the completion of reading data of interest from the memory cell array 50 into the page buffer. The logic controller 41 transfers data stored in the page buffer to the memory controller 2 (see FIG. 1) via the I/O signal line.

Or, for example, the memory controller 2 issues a retry read instruction (CMD-Add-DT) to supply to the memory chip 40 based on the result of the decoder 26 determining whether there is an error in user data or according to a retry read command from the host 4. For example, if the retry read processing according to the retry read instruction (CMD-Add-DT) is shift read processing, then the command analysis circuit 41a can understand whether the shift direction in the shift read processing is plus shift or minus shift because of the command CMD in the retry read instruction (CMD-Add-DT) from the memory controller 2, understand the address (Add) to specify a read voltage Vread, and interpret the data DT as the shift amount for the read voltage in the shift read processing. In the shift read operation, multiple times of operation need to be performed while shifting the read voltage, and hence the total processing time is likely to be longer than in normal read operation.

Or, for example, where the retry read processing is DLA processing, the memory controller 2 issues a read instruction (00h-Add-30h) to read data of adjacent memory cells connected to the word line WLn+1 before reading data of selected memory cells connected to the selected word line WLn and supplies to the memory chip 40. Then the memory controller 2 issues the retry read instruction (CMD-Add-DT) to change the level of the read voltage Vread applied to the selected word line WLn according to the data of the adjacent memory cells and to read data from the selected memory cells and supplies to the memory chip 40. In the DLA processing, because of needing to read data of adjacent memory cells before reading data of selected memory cells, the total processing time is likely to be longer than in normal read operation.

Or, for example, the memory controller 2 issues a program instruction (80h-Add-Data-10h) according to a program command from the host 4 to supply to the memory chip 40. The command analysis circuit 41a can interpret the instruction as a program instruction because of the 80h and 10h of the program instruction (80h-Add-Data-10h) from the memory controller 2, interpret “Add” as the address to program at, and interpret “Data” as data to program. Thus the logic controller 41 performs write processing. In the write processing, the logic controller 41 performs program operation to write data into the memory cell array 50 and then performs program verify operation to verify whether writing has been correctly programmed. Further, the logic controller 41 sets the RY/BY signal (see FIG. 2) to indicate the busy state while it is performing write processing. Then the logic controller 41 switches the RY/BY signal from the busy state to the ready state after the completion of writing data into the memory cell array 50. The logic controller 41 transfers a completion notice to the memory controller 2 via the I/O signal line.

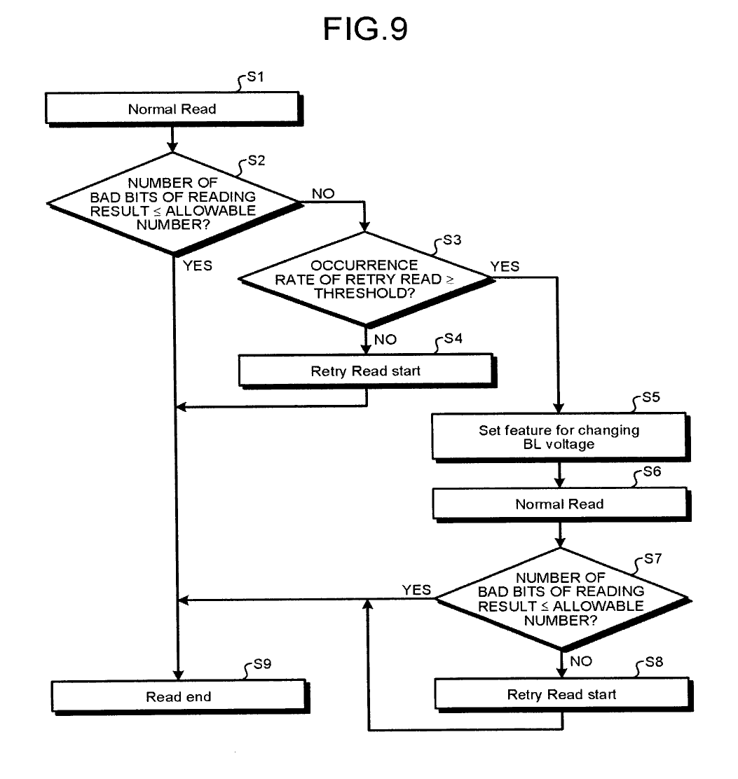

Next, the operation of the host 4 and the semiconductor storage device 1 will be described using FIG. 9. FIG. 9 is a flow chart showing the operation of the host 4 and the semiconductor storage device 1.

When receiving a normal read command from the host 4, the semiconductor storage device 1 performs read operation according to the normal read command (S1) and transmits the reading result including data read from memory cells and information about the number of bad bits to the host 4. The host 4 receives the reading result from the semiconductor storage device 1 and determines whether the number of bad bits of the reading result is less than or equal to an allowable number (S2). If the number of bad bits is less than or equal to the allowable number (Yes at S2), the host 4 finishes a series of read processing (S9).

If the number of bad bits exceeds the allowable number (No at S2), the host 4 determines whether the occurrence rate of the retry read processing is greater than or equal to a threshold (S3). The occurrence rate of the retry read processing can be obtained from, for example:

(the occurrence rate of retry read processing)=(the number of retry read processing times)/((the number of normal read processing times)+(the number of retry read processing times)).

If the occurrence rate of the retry read processing is less than the threshold (No at S3), the host 4 transmits a retry read command to the semiconductor storage device 1. When receiving the retry read command from the host 4, the semiconductor storage device 1 performs retry read operation according to the retry read command (S4) and transmits the reading result including data read from memory cells and information about the number of bad bits to the host 4. When receiving the reading result from the semiconductor storage device 1, the host 4 finishes a series of read processing (S9).

If the occurrence rate of the retry read processing is greater than or equal to the threshold (Yes at S3), the host 4 transmits a set feature command including the request to change the control voltage BLC and the to-be-changed-to value V2 to the semiconductor storage device 1. When receiving the set feature command from the host 4, the semiconductor storage device 1 overwrites/updates the value V1 stored in the BLC register 41c in the memory chip 40 with the value V2 and transmits an update completion notice to the host 4 (S5). The host 4, in response to the update completion notice, transmits a normal read command to the semiconductor storage device 1.

When receiving the normal read command from the host 4, the semiconductor storage device 1 performs read operation according to the normal read command (S6) and transmits the reading result including data read from memory cells and information about the number of bad bits to the host 4. The host 4 receives the reading result from the semiconductor storage device 1 and determines whether the number of bad bits of the reading result is less than or equal to an allowable number (S7). If the number of bad bits is less than or equal to the allowable number (Yes at S7), the host 4 finishes a series of read processing (S9).

If the number of bad bits exceeds the allowable number (No at S7), the host 4 transmits a retry read command to the semiconductor storage device 1. When receiving the retry read command from the host 4, the semiconductor storage device 1 performs retry read operation according to the retry read command (SB) and transmits the reading result including data read from memory cells and information about the number of bad bits to the host 4. When receiving the reading result from the semiconductor storage device 1, the host 4 finishes a series of read processing (S9).

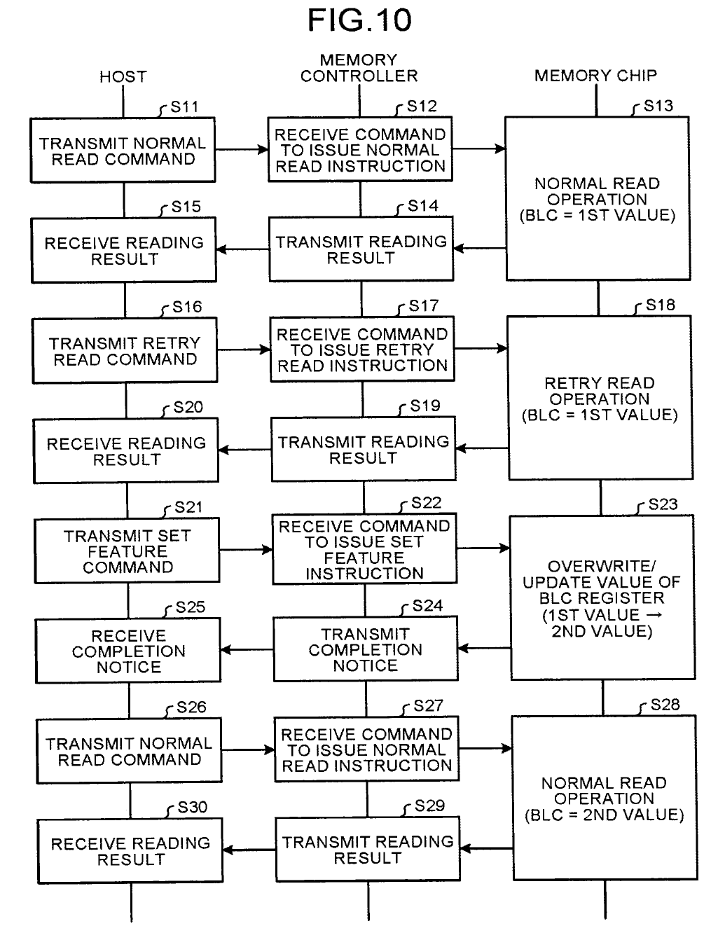

Next, an example of the operation of the host 4, memory controller 2, and memory chip 40 will be described using FIG. 10. FIG. 10 is a sequence diagram showing the operation of the host 4, memory controller 2, and memory chip 40.

The host 4 transmits a normal read command to the semiconductor storage device 1 (S11). When receiving the normal read command from the host 4, the memory controller 2 of the semiconductor storage device 1 issues a normal read instruction according to the normal read command to supply to the memory chip 40 (S12). The memory chip 40, according to the normal read instruction, performs normal read operation while controlling the voltage on the bit line BL by the control voltage BLC having the first value V1 (S13) and transfers the reading result to the memory controller 2. When the reading result is transferred thereto, the memory controller 2 transmits the reading result to the host 4 (S14).

The host 4 receives the reading result (S15) and, according to the reading result (e.g., according to the answer being No at S2, then No at S3 in FIG. 9), transmits a retry read command to the semiconductor storage device 1 (S16). When receiving the retry read command from the host 4, the memory controller 2 of the semiconductor storage device 1 issues a retry read instruction according to the retry read command to supply to the memory chip 40 (S17). The memory chip 40, according to the retry read instruction, performs retry read operation while controlling the voltage on the bit line BL by the control voltage BLC having the first value V1 (S18) and transfers the reading result to the memory controller 2. When the reading result is transferred thereto, the memory controller 2 transmits the reading result to the host 4 (S19).

The host 4 receives the reading result (S20) and, according to the reading result (e.g., according to the answer being Yes at S3 in FIG. 9), transmits a set feature command to the semiconductor storage device 1 (S21). When receiving the set feature command from the host 4, the memory controller 2 of the semiconductor storage device 1 issues a set feature instruction according to the set feature command to supply to the memory chip 40 (S22). The memory chip 40, according to the set feature instruction, overwrites/updates the first value V1 stored in the BLC register 41c with the second value V2 (S23) and transfers an update completion notice to the memory controller 2. When the update completion notice is transferred thereto, the memory controller 2 transmits the update completion notice to the host 4 (S24).

The host 4 receives the update completion notice (S25) and, in response to the update completion notice, transmits a normal read command to the semiconductor storage device 1 (S26). When receiving the normal read command from the host 4, the memory controller 2 of the semiconductor storage device 1 issues a normal read instruction according to the normal read command to supply to the memory chip 40 (S27). The memory chip 40, according to the normal read instruction, performs normal read operation while controlling the voltage on the bit line BL by the control voltage BLC having the second value V2 (S28) and transfers the reading result to the memory controller 2. When the reading result is transferred thereto, the memory controller 2 transmits the reading result to the host 4 (S29).

The host 4 receives the reading result (S30) and, if determining that the normal read operation has been successful, finishes a series of read processing. That is, when memory cells have been degrading, the accuracy of the normal read operation can be improved by changing the value of the control voltage BLC used to control the voltage on the bit line BL from V1 to V2 (>V1).

Note that the retry read processing may be controlled by the memory I/F 22 in response to the controller 23 determining that the retry read processing should be performed, instead of being performed according to a retry read command from the host 4. In this case, S16 may be omitted.

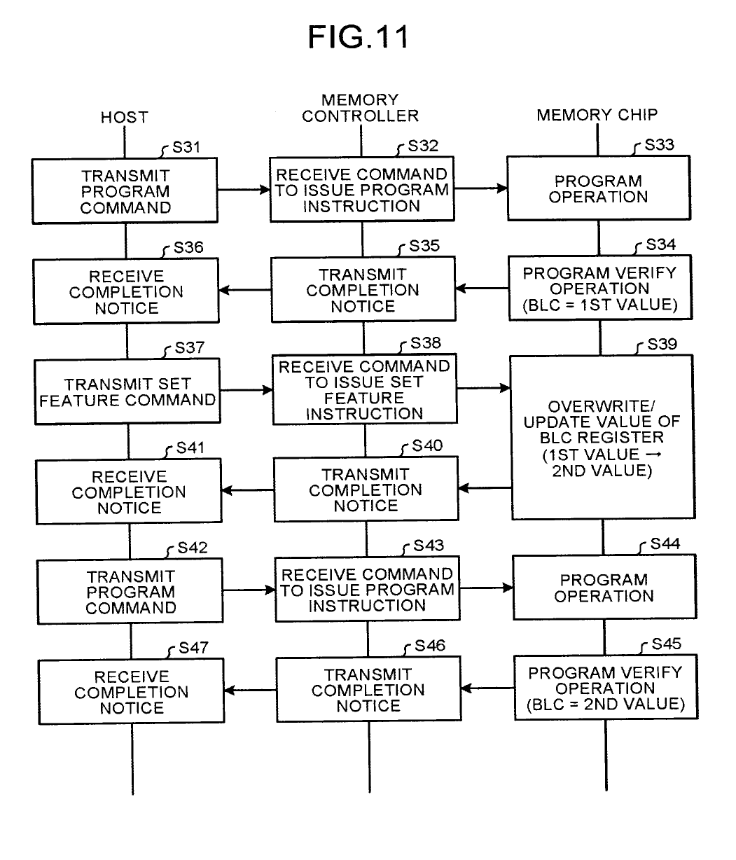

Next, another example of the operation of the host 4, memory controller 2, and memory chip 40 will be described using FIG. 11. FIG. 11 is a sequence diagram showing the operation of the host 4, memory controller 2, and memory chip 40.

The host 4 transmits a program command to the semiconductor storage device 1 (S31). When receiving the program command from the host 4, the memory controller 2 of the semiconductor storage device 1 issues a program instruction according to the program command to supply to the memory chip 40 (S32). The memory chip 40, according to the program instruction, performs program operation (S33). Then the memory chip 40 performs program verify operation while controlling the voltage on the bit line BL by the control voltage BLC having the first value V1 (S34). The memory chip 40 may repeat the program operation (S33) and program verify operation (S34) while increasing the program voltage from an initial value until the program operation is successful. The memory chip 40 transfers a program completion notice including the program verify result to the memory controller 2. When the program completion notice is transferred thereto, the memory controller 2 transmits the program completion notice to the host 4 (S35).

The host 4 receives the program completion notice (S36) and, according to the program verify result included in the program completion notice (e.g., according to the number of times when the program operation and program verify operation have been repeated being less than or equal to a threshold), transmits a set feature command to the semiconductor storage device 1 (S37). When receiving the set feature command from the host 4, the memory controller 2 of the semiconductor storage device 1 issues a set feature instruction according to the set feature command to supply to the memory chip 40 (S38). The memory chip 40, according to the set feature instruction, overwrites/updates the first value V1 stored in the BLC register 41c with the second value V2 (S39) and transfers an update completion notice to the memory controller 2. When the update completion notice is transferred thereto, the memory controller 2 transmits the update completion notice to the host 4 (S40).

The host 4 receives the update completion notice (S41) and, in response to the update completion notice, transmits a program command to the semiconductor storage device 1 (S42). When receiving the program command from the host 4, the memory controller 2 of the semiconductor storage device 1 issues a program instruction according to the program command to supply to the memory chip 40 (S43). The memory chip 40, according to the program instruction, performs program operation (S44). Then the memory chip 40 performs program verify operation while controlling the voltage on the bit line BL by the control voltage BLC having the second value V2 (S45). The memory chip 40 may repeat the program operation (S44) and program verify operation (S45) while increasing the program voltage from an initial value until the program operation is successful. The memory chip 40 transfers a program completion notice including the program verify result to the memory controller 2. When the program completion notice is transferred thereto, the memory controller 2 transmits the program completion notice to the host 4 (S46).

The host 4 receives the program completion notice (S47) and, if determining that the program operation has been successful, finishes a series of program processing. That is, when memory cells have been degrading, the accuracy of the program verify operation can be improved by changing the value of the control voltage BLC used to control the voltage on the bit line BL from V1 to V2 (>V1).

As described above, in the embodiment, when receiving a command (e.g., a set feature command) including a request to change the control voltage BLC and the to-be-changed-to value V2 (the second value) from the host 4, the semiconductor storage device 1, according to the request to change, changes the value of the control voltage BLC used to control the voltage on the bit line BL from V1 to V2 (>V1). Thus, the semiconductor storage device 1 can raise the potential Vb1 on the precharged bit line BL according to specification from the user side (host 4 side). That is, because the user side (host 4 side) can specify to what degree to raise the potential Vb1 on the precharged bit line BL, degradation in the reliability of the read operation or the program verify operation can be suppressed to an appropriate degree taking into account compatibility between the semiconductor storage device 1 and the host 4.

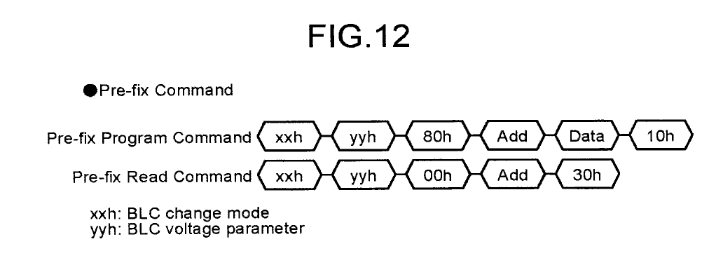

Note that various commands can be used as the command including a request to change the control voltage BLC and the to-be-changed-to value V2 (the second value), not being limited to a set feature command (see FIG. 8). For example, a prefix command as shown in FIG. 12 can be used. FIG. 12 is a diagram showing the command sequence of the prefix command. The prefix command includes a prefix program command and a prefix read command. In the prefix program command, xxh and yyh, where xx, yy can each take on any value, are added to the beginning of the command sequence of a program command (write request). In the prefix read command, xxh and yyh are added to the beginning of the command sequence of a read command (read request). The host 4 sets the xxh to specify an instruction to change that is a request to change the control voltage BLC and the yyh to specify the to-be-changed-to value V2 (the second value).

The command analysis circuit 41a shown in FIG. 3 can interpret the prefix program command or prefix read command as an instruction to change because of the xxh. Then the command analysis circuit 41a, according to the instruction to change, interprets the value of the yyh as specifying the to-be-changed-to value V2 (the second value). Then the command analysis circuit 41a, according to the instruction to change, instructs the register control circuit 41b to change the value V1 of the control voltage BLC to the value V2.

The register control circuit 41b, according to the instruction from the command analysis circuit 41a, stores the value V2 into the BLC register 41c instead of the value V1. That is, the register control circuit 41b overwrites/updates the value V1 stored in the BLC register 41c with the value V2.

The logic controller 41 refers to the value V2 stored in the BLC register 41c and controls the power supply circuit 49 to generate the control voltage BLC having the value V2. Thus, the power supply circuit 49 can generate the control voltage BLC having the value V2 to apply to the gate of the transistor Tr1 in each sense amplifier SA. Therefore the potential Vb1 on the precharged bit line BL can be raised according to specification from the user side (host 4 side).

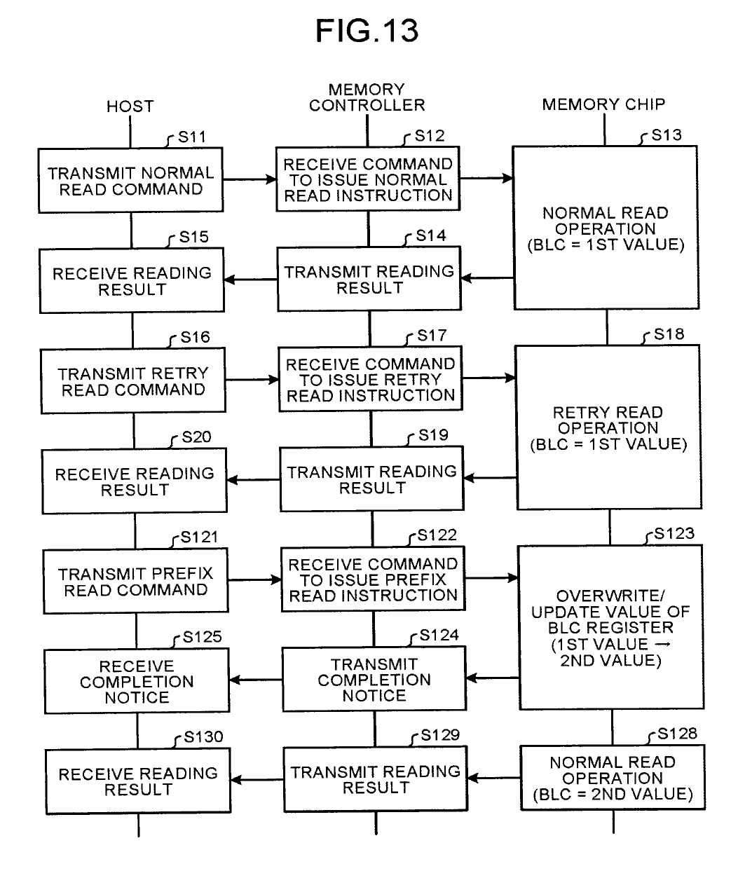

In this case, the operation of the host 4, memory controller 2, and memory chip 40 can be simplified as shown in FIG. 13, for example. FIG. 13 is a sequence diagram showing the operation of the host 4, memory controller 2, and memory chip 40.

When receiving the reading result (S20), the host 4, according to the reading result (e.g., according to the answer being Yes at S3 in FIG. 9), transmits a prefix read command to the semiconductor storage device 1 (S121). When receiving the prefix read command from the host 4, the memory controller 2 of the semiconductor storage device 1 issues a prefix read instruction according to the prefix read command to supply to the memory chip 40 (S122). The memory chip 40, according to the instruction to change and the second value V2 included in the prefix read instruction, overwrites/updates the first value V1 stored in the BLC register 41c with the second value V2 (S123) and transfers an update completion notice to the memory controller 2. When the update completion notice is transferred thereto, the memory controller 2 transmits the update completion notice to the host 4 (S124).

The host 4 receives the update completion notice (S125) and waits until receiving the reading result. Meanwhile, the memory chip 40, according to the read request included in the prefix read instruction, performs normal read operation while controlling the voltage on the bit line BL by the control voltage BLC having the second value V2 (S128) and transfers the reading result to the memory controller 2. When the reading result is transferred thereto, the memory controller 2 transmits the reading result to the host 4 (S129).

The host 4 receives the reading result (S130) and, if determining that the normal read operation has been successful, finishes a series of read processing. That is, when memory cells have been degrading, the accuracy of the normal read operation can be improved by changing the value of the control voltage BLC used to control the voltage on the bit line BL from V1 to V2 (>V1). Also, the series of read processing can be simplified.

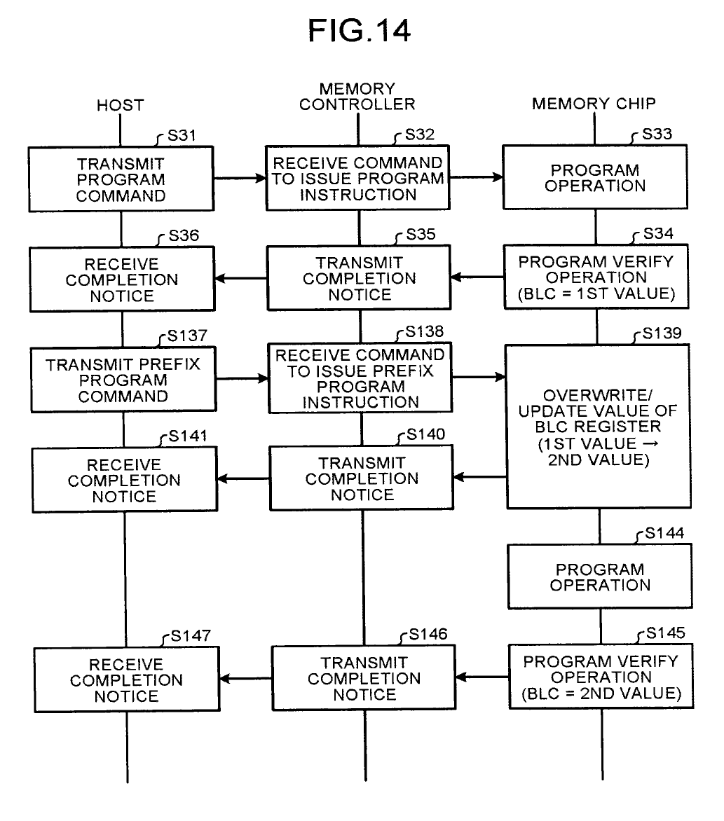

Or the operation of the host 4, memory controller 2, and memory chip 40 can be simplified as shown in FIG. 14, for example. FIG. 14 is a sequence diagram showing the operation of the host 4, memory controller 2, and memory chip 40.

When receiving the program completion notice (S36), the host 4, according to the program verify result included in the program completion notice (e.g., according to the number of times when the program operation and program verify operation have been repeated being less than or equal to a threshold), transmits a prefix program command to the semiconductor storage device 1 (S137). When receiving the prefix program command from the host 4, the memory controller 2 of the semiconductor storage device 1 issues a prefix program instruction according to the prefix program command to supply to the memory chip 40 (S138). The memory chip 40, according to the instruction to change and the second value V2 included in the prefix program instruction, overwrites/updates the first value V1 stored in the BLC register 41c with the second value V2 (S139) and transfers an update completion notice to the memory controller 2. When the update completion notice is transferred thereto, the memory controller 2 transmits the update completion notice to the host 4 (S140).

The host 4 receives the update completion notice (S141) and waits until receiving a program completion notice. Meanwhile, the memory chip 40, according to the write request included in the prefix program instruction, performs program operation (S144). Then the memory chip 40 performs program verify operation while controlling the voltage on the bit line BL by the control voltage BLC having the second value V2 (S145). The memory chip 40 may repeat the program operation (S144) and program verify operation (S145) while increasing the program voltage from an initial value until the program operation is successful. The memory chip 40 transfers a program completion notice including the program verify result to the memory controller 2. When the program completion notice is transferred thereto, the memory controller 2 transmits the program completion notice to the host 4 (S146).

The host 4 receives the program completion notice (S147) and, if determining that the program operation has been successful, finishes a series of program processing. That is, when memory cells have been degrading, the accuracy of the program verify operation can be improved by changing the value of the control voltage BLC used to control the voltage on the bit line BL from V1 to V2 (>V1). Also, the series of program processing can be simplified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell array having multiple memory cells connected to word lines and bit lines; and
a control circuit that sets a value of a control voltage used to control voltages on the bit lines at a first value and, if receiving a first command including a change request to change the control voltage and including a to-be-changed-to second value, changes the value of the control voltage used to control the voltages on the bit lines from the first value to the second value, according to the change request.

2. The semiconductor storage device according to claim 1, wherein
the control circuit has a bit-line control register storing the first value,
wherein if receiving the first command, the control circuit stores the second value into the bit-line control register instead of the first value, according to the change request, and
wherein if receiving a second command including a read request, the control circuit performs read operation according to the read request, while controlling the voltages on the bit lines to be at a level corresponding to the control voltage having the second value stored in the bit-line control register.

3. The semiconductor storage device according to claim 1, wherein
the control circuit has a bit-line control register storing the first value,
wherein if receiving the first command, the control circuit stores the second value into the bit-line control register instead of the first value, according to the change request, and
wherein if receiving a third command including a write request, the control circuit performs program verify operation according to the write request, while controlling the voltages on the bit lines to be at a level corresponding to the control voltage having the second value stored in the bit-line control register.

4. The semiconductor storage device according to claim 1, wherein
the control circuit has a bit-line control register storing the first value,
wherein if receiving the first command including the change request, the second value, and a read request, the control circuit stores the second value into the bit-line control register instead of the first value, according to the change request, and
wherein the control circuit performs read operation according to the read request, while controlling the voltages on the bit lines to be at a level corresponding to the control voltage having the second value stored in the bit-line control register.

5. The semiconductor storage device according to claim 1, wherein
the control circuit has a bit-line control register storing the first value,
wherein if receiving the first command including the change request, the second value, and a read request, the control circuit stores the second value into the bit-line control register instead of the first value, according to the change request, and
wherein the control circuit performs program verify operation according to the write request, while controlling the voltages on the bit lines to be at a level corresponding to the control voltage having the second value stored in the bit-line control register.

6. The semiconductor storage device according to claim 2, wherein
the first command includes address information of the bit-line control register and the second value, and
wherein the control circuit stores the second value into the bit-line control register instead of the first value, according to the address information.

7. The semiconductor storage device according to claim 1, wherein
the control circuit has:
a transistor electrically connected between a sense node and each of the bit lines and having a control voltage applied to a gate thereof; and
a controller that controls the value of the control voltage applied to the gate of the transistor to change from the first value to the second value according to the change request.

8. The semiconductor storage device according to claim 7, wherein
the control circuit further has a power supply circuit that generates a control voltage,
wherein the transistor has the control voltage generated by the control circuit applied to the gate thereof, and
wherein the controller controls the value of the control voltage generated by the control circuit to change from the first value to the second value according to the change request.

9. The semiconductor storage device according to claim 1, wherein
the control circuit performs read operation according to a read request and performs second read operation higher in reliability than the read operation according to a second read request.

10. The semiconductor storage device according to claim 9, wherein
after performing the second read operation according to the second read request, the control circuit performs the read operation according to the read request, while controlling the voltages on the bit lines to be at a level corresponding to the control voltage having the second value according to the change request.

11. A control method of a semiconductor storage device which has a memory cell array having multiple memory cells connected to word lines and bit lines, comprising:
setting value of a control voltage used to control voltages on the bit lines at a first value; and
if receiving a first command including a change request to change the control voltage and a to-be-changed-to second value, changing the value of the control voltage used to control the voltages on the bit lines from the first value to the second value, according to the change request.

12. The control method of the semiconductor storage device according to claim 11, wherein
setting the value of the control voltage at the first value includes storing the first value into a bit-line control register,
wherein changing the value of the control voltage from the first value to the second value includes, if receiving the first command, storing the second value into the bit-line control register instead of the first value, according to the change request, and
wherein the control method further comprises, if receiving a second command including a read request, performing read operation according to the read request, while controlling the voltages on the bit lines to be at a level corresponding to the control voltage having the second value stored in the bit-line control register.

13. The control method of the semiconductor storage device according to claim 11, wherein
setting the value of the control voltage at the first value includes storing the first value into a bit-line control register,
wherein changing the value of the control voltage from the first value to the second value includes, if receiving the first command, storing the second value into the bit-line control register instead of the first value, according to the change request, and
wherein the control method further comprises, if receiving a third command including a write request, performing program verify operation according to the write request, while controlling the voltages on the bit lines to be at a level corresponding to the control voltage having the second value stored in the bit-line control register.

14. The control method of the semiconductor storage device according to claim 11, wherein
setting the value of the control voltage at the first value includes storing the first value into a bit-line control register,
wherein changing the value of the control voltage from the first value to the second value includes, if receiving the first command including the change request, the second value, and a read request, storing the second value into the bit-line control register instead of the first value, according to the change request, and
wherein the control method further comprises performing read operation according to the read request, while controlling the voltages on the bit lines to be at a level corresponding to the control voltage having the second value stored in the bit-line control register.

15. The control method of the semiconductor storage device according to claim 11, wherein
setting the value of the control voltage at the first value includes storing the first value into a bit-line control register,
wherein changing the value of the control voltage from the first value to the second value includes, if receiving the first command including the change request, the second value, and a write request, storing the second value into the bit-line control register instead of the first value, according to the change request, and
wherein the control method further comprises performing program verify operation according to the write request, while controlling the voltages on the bit lines to be at a level corresponding to the control voltage having the second value stored in the bit-line control register.

16. The control method of the semiconductor storage device according to claim 12, wherein
the first command includes address information of the bit-line control register and the second value, and
wherein storing the second value into the bit-line control register includes, storing the second value into the bit-line control register instead of the first value, according to the address information.

17. The control method of the semiconductor storage device according to claim 11, wherein
setting the value of the control voltage at the first value includes setting the value of the control voltage applied to the gate of a transistor electrically connected between a sense node and each of the bit lines at the first value, and
wherein changing the value of the control voltage from the first value to the second value includes changing the value of the control voltage applied to the gate of the transistor from the first value to the second value according to the change request.

18. The control method of the semiconductor storage device according to claim 17, wherein
setting the value of the control voltage at the first value includes setting the value of the control voltage generated by a power supply circuit to be applied to the gate of the transistor at the first value, and
wherein changing the value of the control voltage from the first value to the second value includes changing the value of the control voltage generated by the power supply circuit from the first value to the second value according to the change request.

19. The control method of the semiconductor storage device according to claim 11, further comprising:
performing read operation according to a read request; and
performing second read operation higher in reliability than the read operation according to a second read request.

20. The control method of the semiconductor storage device according to claim 19, further comprising,
after performing the second read operation, performing the read operation according to the read request, while controlling the voltages on the bit lines to be at a level corresponding to the control voltage having the second value according to the change request.
